(19) United States
(12) Patent Application Publication
(10) Pub. No.: US 2013/0130610 A1
(43) Pub. Date: May 23, 2013

(54) INFORMATION PROCESSING APPARATUS AND METHOD OF CONTROLLING A COOLING FAN

(71) Applicant: Sohei Unno, Ome-shi (JP)

(72) Inventor: Sohei Unno, Ome-shi (JP)

(21) Appl. No.: 13/483,395

(22) Filed: May 30, 2012

(30) Foreign Application Priority Data
Nov. 18, 2011 (JP) 2011-252660

(51) Int. Cl. F24F 11/04; H05K 5/02

(52) U.S. Cl. 454/184

(57) ABSTRACT

According to one embodiment, an information processing apparatus includes a housing and a cooling fan controller. The housing is configured to be placed inside a rack in a third direction which is opposed to a case where a first side is horizontal, and a second side orthogonal to the first side is in the second direction. The cooling fan controller is configured to set a rotating speed of a cooling fan at different values between a case where a detection result of a sensor indicates that a housing is placed in either a first direction or a second direction and a case where the detection result of the sensor indicates that the housing is placed in a third direction.

### CROSS-REFERENCE TO RELATED APPLICATIONS

This application is based upon and claims the benefit of priority from prior Japanese Patent Application No. 2011-252660, filed Nov. 18, 2011, the entire contents of which are incorporated herein by reference.

### FIELD

Embodiments described herein relate generally to an information processing apparatus and a method of controlling a cooling fan.

### BACKGROUND

In general, information processing apparatuses, such as a server or a personal computer, are provided with a cooling fan for cooling the interior of their housings. The information processing apparatuses include apparatuses which are configured to enable a number of placement manners, i.e., vertical placement and horizontal placement. The cooling efficiency of the cooling fan differs depending upon how the information apparatus is placed. For example, when the apparatus is placed vertically, the cooling fan is located on top of the housing, and the cooling efficiency is high. On the other hand, when the apparatus is placed horizontally, the cooling fan is located on a side of the housing, and the cooling efficiency is low.

It may be thought to provide employ a temperature sensor to monitor the temperature in the interior of the housing. However, since the temperature sensor is a comparatively high-cost electronic component, various proposals have been made to properly control the cooling fan without using the temperature sensor.

As a method for determining how an information processing apparatus is placed, it is known in the art to employ a triaxial acceleration sensor having a function of detecting the direction of gravity. However, the cooling fan of an information processing apparatus placed horizontally may provide different cooling efficiencies, depending upon whether or not the information processing apparatus is placed in a rack. Likewise, the cooling fan of the information processing apparatus placed vertically may provide different cooling efficiencies, depending upon whether or not the air exhaust port is located near a wall surface.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary diagram schematically illustrating a system configuration of an information processing apparatus according to the first embodiment.

FIG. 2 is an exemplary view showing an outward appearance of the information processing apparatus and showing the first placement (vertical placement) supported by the first embodiment.

FIG. 3 is an exemplary view showing an outward appearance of the information processing apparatus and showing the second placement (horizontal placement) supported by the first embodiment.

FIG. 4 is an exemplary view showing an outward appearance of the information processing apparatus and showing the third placement (rack mount placement) supported by the first embodiment.

FIG. 5 is an exemplary view of the information processing apparatus of the first embodiment and showing an example of a manner in which the apparatus can be mounted in the rack in the right direction.

FIG. 6 is an exemplary diagram schematically illustrating a system configuration of an information processing apparatus according to the second embodiment.

FIG. 7 is an exemplary view showing an outward appearance of the information processing apparatus of the second embodiment.

FIG. 8 is an exemplary conceptual diagram illustrating procedures for controlling cooling fans of the information processing apparatus of the second embodiment.

### DETAILED DESCRIPTION

Various embodiments will be described hereinafter with reference to the accompanying drawings.

In general, according to one embodiment, an information processing apparatus includes a housing, a sensor, a cooling fan, and a cooling fan controller. The housing has a rectangular front face and is configured to be placed in either a first direction in which a first side in a longitudinal direction of the front face is vertical or a second direction in which the first side is horizontal. The sensor is configured to sense a placement direction of the housing. The cooling fan controller is configured to control a rotating speed of the cooling fan based on a detection result of the sensor. The housing is configured to be placed inside a rack in a third direction which is opposed to a case where the first side is horizontal, and a second side orthogonal to the first side is in the second direction. The cooling fan controller is further configured to set a rotating speed of the cooling fan at different values between a case where the detection result of the sensor indicates that the housing is placed in either the first direction or the second direction and a case where the detection result of the sensor indicates that the housing is placed in the third direction, such that the rotating speed of the cooling fan is controlled at different values between a case where the housing is placed outside the rack and a case where the housing is placed inside the rack.

### First Embodiment

A description will be first given of the first embodiment.

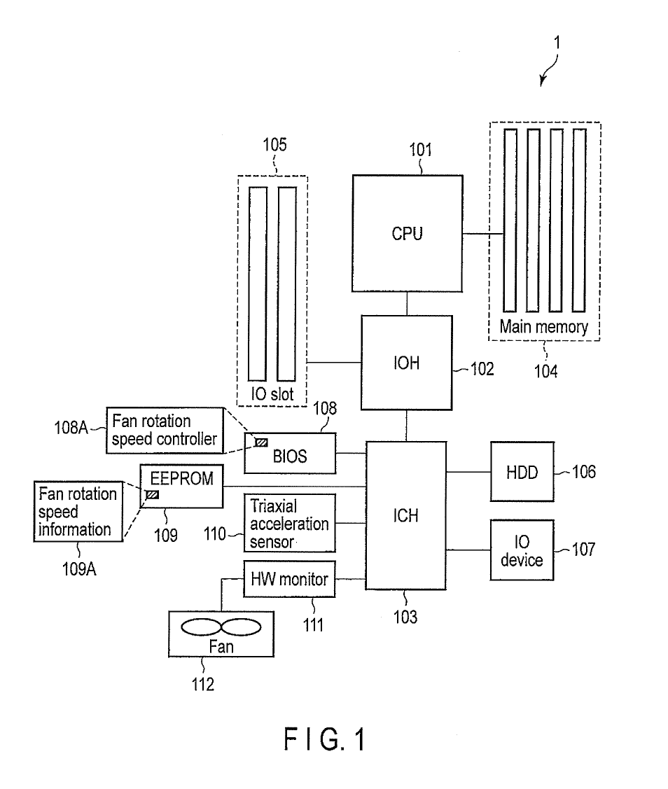

FIG. 1 is an exemplary diagram schematically illustrating a system configuration of an information processing apparatus 1 according to the first embodiment. The information processing apparatus 1 is embodied as a computer referred to as a server.

As shown in FIG. 1, the information processing apparatus 1 includes a central processing unit (CPU) 101, an input/output HUB (IOH) 102, an input/output control HUB (ICH) 103, a main memory 104, an IO slot 105, a hard disk drive (HDD) 106, an IO device 107, a basic input/output system read only memory (BIOS-ROM) 108, an electrically erasable programmable ROM (EEPROM) 109, a triaxial acceleration sensor 110, a hardware (HW) monitor 111, a cooling fan 112, etc.

The triaxial acceleration sensor 110 is a sensor provided for detecting the direction in which the housing is placed. The triaxial acceleration sensor 110 may be replaced with any type of sensor as long as the alternative sensor can detect the direction in which the housing is placed.

The CPU 106 loads various kinds of programs in a main memory 104 from the HDD 106, for example. The CPU 101 generates heat and radiates it inside the housing. The cooling fan 112 takes in the outside air through an air intake port and discharges the heat inside the housing by way of an exhaust port. The cooling fan 112 is provided, for example, in the neighborhood of an air intake port 11. The cooling fan 112 is controlled and monitored by the HW monitor 111.

The BIOS stored in the BIOS-ROM 106 (the BIOS may be referred to as BIOS 108 hereinafter) is a program for hardware control, and includes a fan rotation speed controller 108A. The fan rotation speed controller 108A of BIOS 108 is configured to properly control the rotation speed of the cooling fan 112 by means of the HW monitor 111.

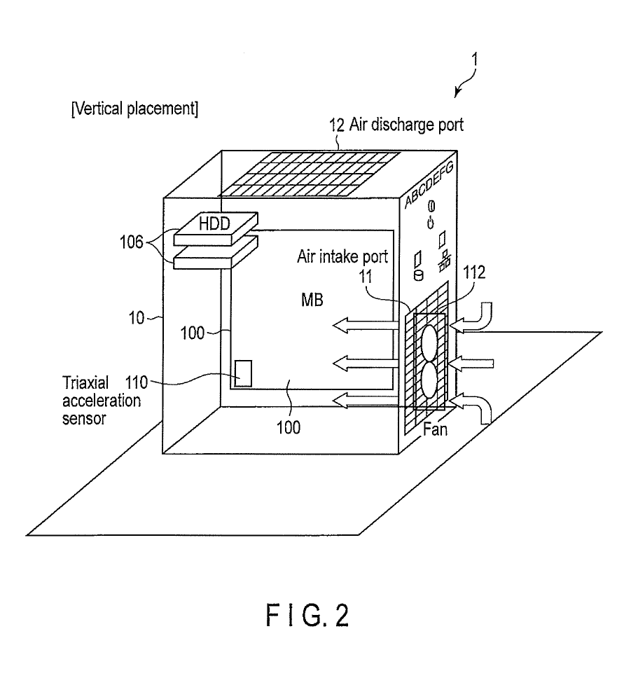

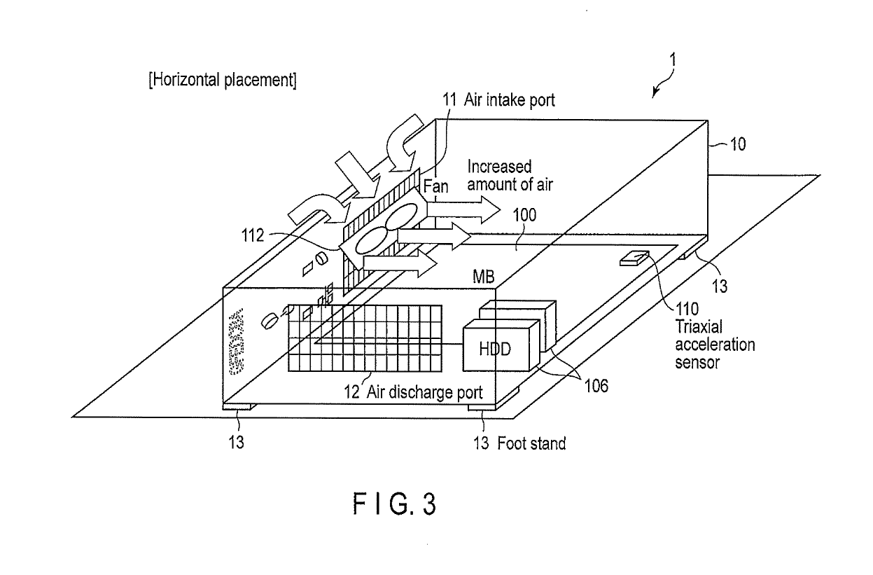

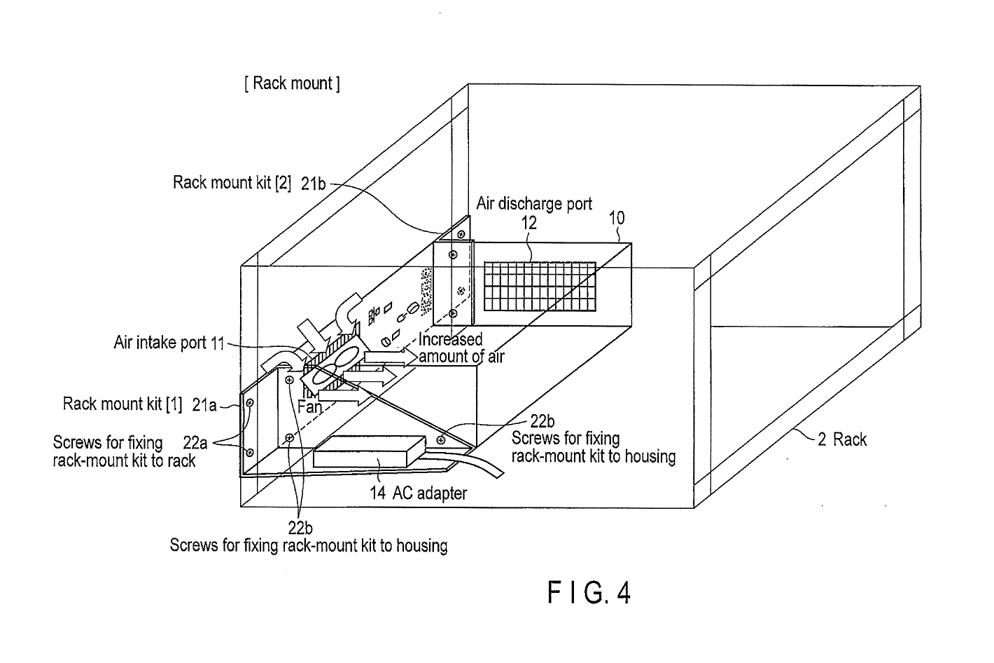

A description will be given with reference to FIG. 2, FIG. 3 and FIG. 4 of the placement manners supported by the information processing apparatus 1 and of the basic control principles based on which the information processing apparatus 1 supporting the placement manners controls the cooling fan 112 for each placement manner.

FIG. 2 is an exemplary view showing an outward appearance of the information processing apparatus and showing the first placement (vertical placement) supported by the first embodiment.

As shown in FIG. 2, the information processing apparatus 1 has a box-shaped housing 10. The housing 10 of the information processing apparatus 1 supports vertical placement wherein the longitudinal direction of the rectangular front face (i.e., the front panel having the logotype “ABCDEFG” thereon) is the same as the vertical direction. An air intake port 11 is formed in the front face of the housing 10, and an air discharge port 12 for discharging the heat generated by the components (e.g., the CPU 101) on a motherboard (MB) 100 is formed in the top face in the case of the vertical placement. As described above, it is assumed that the cooling fan 112 of the information processing apparatus 1 is located close to the air intake port 11.

FIG. 3 is an exemplary view showing an outward appearance of the information processing apparatus 1 and showing the second placement (horizontal placement) supported by the first embodiment.

As shown in FIG. 3, the housing 10 of the information processing apparatus 1 supports horizontal placement wherein the longitudinal direction of the rectangular front face is the same as the horizontal direction. Foot stands 13 are provided at the respective four corners of the bottom face of the housing 10 in the case of the horizontal placement. The foot stands 13 also serve to prevent the image processing apparatus from being mistakenly placed upside down.

In the case of the vertical placement shown in FIG. 2, the air discharge port 12 is located on top of the housing 10. In contrast, in the horizontal placement shown in FIG. 3, the air discharge port 12 is located on one side of the housing 10. Since heat travels upward, the cooling efficiency of the cooling fan 112 inevitably deteriorates in the horizontal placement (wherein the air discharge port 12 is located on one side of the housing 10), as compared to the vertical placement (wherein the air discharge port 12 is located on top).

In view of this problem, if a detection result of the triaxial acceleration sensor 110 indicates horizontal placement, the fan rotation speed controller 108A sets the rotating speed of the cooling fan 112 at a large value, as compared to the case where the detection result indicates vertical placement. The rotating speed of the cooling fan 112 set for the vertical placement and the rotating speed of the cooling fan 112 set for the horizontal placement are stored in the EEPROM 109 as fan rotation speed information 109A.

FIG. 4 is an exemplary view showing an outward appearance of the information processing apparatus and showing the third placement (rack mount placement) supported by the first embodiment.

As shown in FIG. 4, the housing 10 of the information processing apparatus 1 supports a so-called rack mount placement wherein the housing 10 is mounted inside a rack 2 by means of rack mount kits 21a and 21b. The rack mount kits 21a and 21b are fixed to the rack 2 by means of screws 22a (used for fixing the rack mount kits to the rack), and are also fixed to the housing 10 by means of screws 22b (used for fixing the rack mount kits to the housing).

Rack mount kit [1]21a and rack mount kit [2]21b have different structures. When properly fixed, rack mount kit [1]21a provides a space for installing an AC adapter 14 for supplying external power to the information processing apparatus 1. In other words, if rack mount kit [2]21b is incorrectly attached, a mount base is directed downward, and the AC adapter 14 cannot be placed on the mount base and falls. In this way, rack mount kits 21a and 21b are structured so that they can be correctly attached to the rack 2.

When rack mount kit [1]21a is attached to the housing 10, it is prevented from being attached in an undesired manner, because the relationships (positions and numbers) between the screws 22b used for fixing the rack mount kit to the housing and screw holes formed in the housing 10 are so determined as to prevent the incorrect attachment. That is, the housing 10 of the information processing apparatus 1 can be provided inside the rack 2 in the correct direction.

As shown in FIG. 4, when the housing 10 of the information processing apparatus 10 is in the rack mount state, the longitudinal direction of the front face is horizontal. This state is the same as the horizontal placement shown in FIG. 3. Needless to say, the cooling efficiency of the cooling fan 112 is lower inside the rack than outside the rack.

In view of this problem, the information processing apparatus 1 is configured such that the housing 10 in the rack mount placement is reverse to that in the horizontal placement (the top face of the housing 10 in the horizontal placement becomes the bottom face of the housing 10). As described above, the housing 10 of the information processing apparatus 1 is configured in such a manner that it is received inside the rack 2 in the right direction. This right direction is a direction that causes the top and bottom faces of the housing 10 to be reversed to the top and bottom faces of the housing 10 in the horizontal placement. To be more specific, the housing 10 is mounted inside the rack 2, with the foot stands 13 directed upward.

With this structure, the triaxial acceleration sensor 110 not only discriminates between the vertical placement and the horizontal placement but also discriminates between the horizontal placement and the rack mount placement. When a detection result of the triaxial acceleration sensor 110 indicates the rack mount placement, the fan rotation speed controller 108A of the BIOS 108 sets the rotating speed of the cooling fan 112 at a large value, as compared to the case where the detection result indicates vertical placement. The rotating speed of the cooling fan 112 set for the rack mount placement is also stored in the EEPROM 109 as fan rotation speed information 109A.

As described above, the housing 10 in the rack mount placement is reverse to the housing 10 in the horizontal placement. Accordingly, the information processing apparatus 1 makes efficient use of the existing type of triaxial acceleration sensor 110 and controls the rotating speed of the cooling fan 112 properly in accordance with the temperature inside the rack or the temperature outside the rack and without incurring any cost increase. In this way, the cooling fan can be properly controlled in accordance with each of the supported placements.

The rack mount kits 21a and 21b were described as being properly attached to the housing 10 based on the relationships between the screws 22b used for fixing the rack mount kit to the housing and screw holes formed in the housing 10. Needless to say, this is merely one way for attachment, and various methods can be used instead.

For example, a hole may be formed only in a side portion of rack mount kit [2]21b in the rack mount placement that is closer to the air discharge port 12 of the housing 10. The hole is not formed at the middle position as viewed in the height direction of rack mount kit [2]21b but is shifted either upward or downward. A projection is formed at the corresponding position of the housing 10. If the rack mount kits 21a and 21b are attached to the housing 10 in a reverse way (that is, the right rack mount kit is attached to where the left rack mount kit should be), the projection on the housing 10 prevents the attachment operation from being continued. Therefore, the operator is guided to attach the rack mount kits 21a and 21b to their proper positions. Correct attachment of the rack mount kits 21a and 21b may be accomplished by forming a hole in rack mount kit [1]21a (the other rack mount kit) and providing a projection at the corresponding position of the housing 10. If this alternative method is adopted, however, the face of the housing 10 where the air discharge port 12 is provided is the top face in the vertical placement of the housing. It is therefore desirable that the projection be provided on the same face as the air discharge port 12 (the projection should not be provided on the face used as the bottom face).

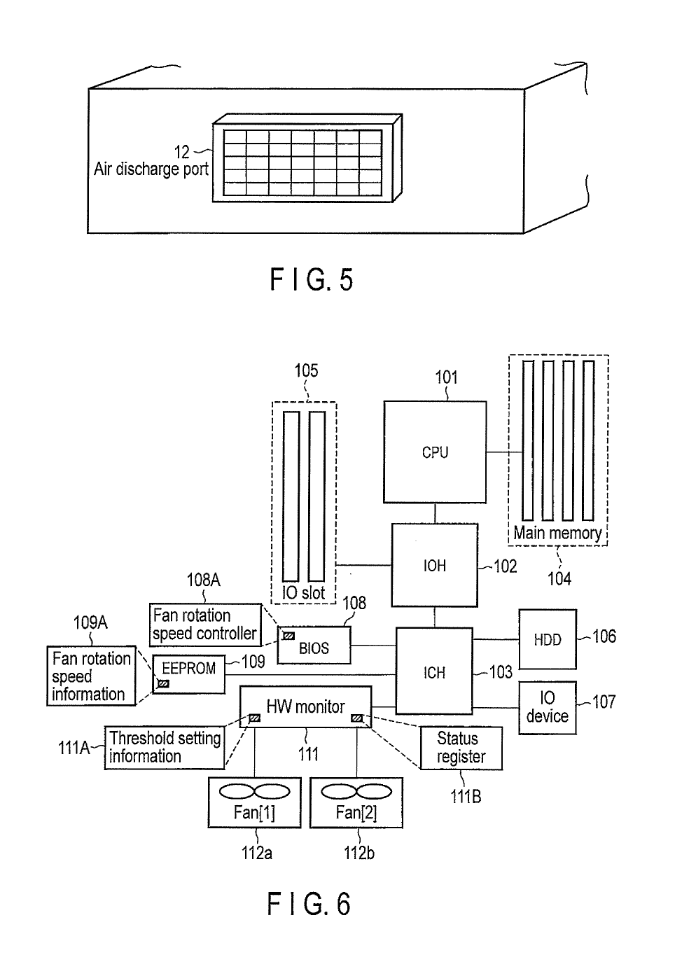

As shown in FIG. 5, the portion of the housing 10 where the air discharge port 12 is provided may be projected from the other portions. This structure prevents rack mount kit [1]21a (which has such a structure as to provide a space for the AC adapter) from being attached to the side of the air discharge port 12.

If the logotype on the front panel of the information processing apparatus is prepared for the horizontal placement, the characters of the logotype will be upside down. Therefore, the logotype should be prepared preferably for the vertical placement, as shown in FIG. 2. If prepared for the vertical placement, the logotype on the front panel does not cause a feeling of strangeness in both the vertical placement and the rack mount placemen, as shown in FIG. 3 and FIG. 4.

### Second Embodiment

A description will now be given of the second embodiment.

FIG. 6 is an exemplary diagram schematically illustrating a system configuration of an information processing apparatus 1 according to the second embodiment. The information processing apparatus 1 is embodied as a computer referred to as a server.

As shown in FIG. 6, the information processing apparatus 1 includes a CPU 101, an IOH 102, an ICH 103, a main memory 104, an IO slot 105, an HDD 106, an IO device 107, a BIOS-ROM 108, an EEPROM 109, an HW monitor 111, cooling fans 112a and 112b, etc. The information processing apparatus 1 of the second embodiment differs from that of the first embodiment in that the triaxial acceleration sensor 110 described above is not provided and that two cooling fans 112a and 112b are employed. It should be noted that the number of cooling fans may be three or more.

In the information processing apparatus 1 of the second embodiment, the HW monitor 11 is configured to store setting information 111A. The threshold setting information 111A are information representing the upper limit thresholds and lower limit thresholds of the rotating speeds of the cooling fans 112a and 112b. The HW monitor 111 monitors whether the rotating speeds of the cooling fans 112a and 112b exceed the upper limit thresholds or if they are lower than the lower limit thresholds. The HW monitor 111 includes a status register 111B configured to record the occurrence of an abnormality of the cooling fans 112a and 112b.

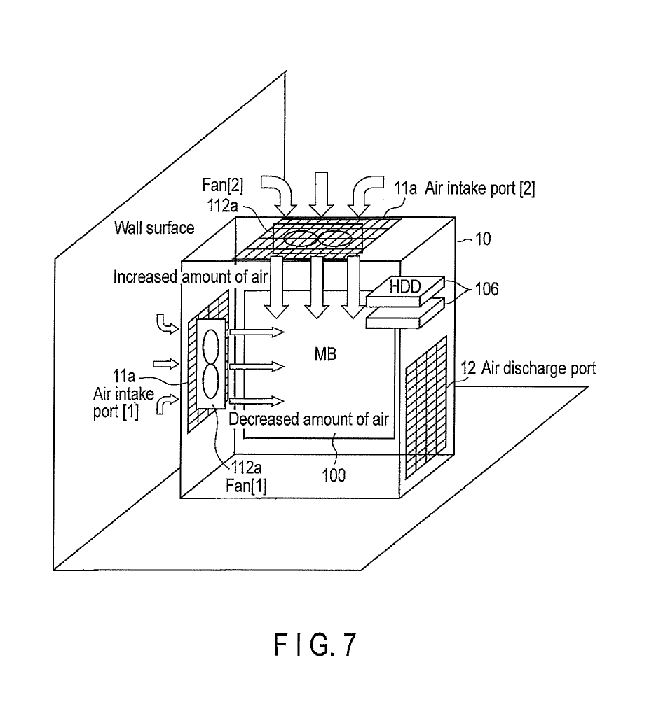

FIG. 7 is an exemplary view showing an outward appearance of the information processing apparatus of the second embodiment.

As shown in FIG. 7, the information processing apparatus 1 includes two air intake ports 11a and 11b. The two air intake ports 11a and 11b are provided for different faces of the housing 10. As described above, the information processing apparatus 1 includes two cooling fans 112a and 112b, and are located in the neighborhood of the two cooling fans 112a and 112b, as shown in FIG. 7.

Let us assume that the housing 10 of the information processing apparatus 1 is placed close to a wall surface in such a manner that the air intake port [1]11a of cooling fan [1]112a is obstructed or covered. In this case, the amount of air taken in by the cooling fan [1]112a decreases, and a sufficient amount of air cannot be supplied into the housing to sufficiently cool the components. To solve this problem, the information processing apparatus 1 increases the rotating speed of cooling fan [1]112b to take in more air, and the decrease in the amount of air taken in by cooling fan [1]112a is compensated for.

To be more specific, when an air intake port is close to a wall surface, the static pressure in the housing increases, and the rotating speed of the cooling fan increases, accordingly. The rotating speed may increase but the amount of air taken in decreases. In view of this phenomenon, if at the time of shipping, the HW monitor 111 detects a value exceeding the upper limit threshold (default value) represented by the threshold setting information 111A, then the fan rotation speed controller 108A of the BIOS 108 determines that the amount of air taken in decreases. In the case shown in FIG. 7, it is detected that the amount of air taken in by cooling fan [1]112a decreases.

Upon detection that the rotating speed of cooling fan [1]112a has exceeded the upper limit threshold represented by the threshold setting information 111A, the HW monitor 111 sets the status register 111B and notifies the BIOS 108 of this state by causing the ICH 103 to generate a system management interrupt (SMI) supplied to the CPU 101. Upon receipt of this notice, the BIOS 108 refers to the status register 111B of the HW monitor 111 and recognizes that the rotating speed of the cooling fan [1]112a has exceeds the upper limit threshold, causing the SMI.

Upon detection of a decrease in the amount of air taken in by cooling fan [1]112a (and of the fact that the decrease is caused by the rotating speed exceeding the upper limit threshold, not by the rotating speed becoming lower than the lower limit threshold), the fan rotation speed controller 108A increases the rotating speed of cooling fan [2]112b by means of the HW monitor 111, in order to compensate for the decrease in the amount of air taken in by cooling fan [1]112a. The fan rotation speed information 109A stored in the EEPROM 109 of the information processing apparatus 1 includes information used for determining how much the rotating speed of cooling fan [2]112b should be increased in accordance with an increase in the rotating speed of cooling fan [1]112a. After being increased, the rotating speed should be higher than the upper limit threshold (default value).

When the rotating speed of cooling fan [2]112b increases to a predetermined value, the HW monitor 111 detects that the rotating speed of cooling fan [2]112b exceeds the upper limit value. Then, the HW monitor 111 sets the status register 111B and causes the ICH 103 to generate an SMI supplied to the CPU 101.

Upon receipt of this notice, the fan rotation speed controller 108A of the BIOS 108 resets the status register 111B of the HW monitor 111 and resets the threshold setting information 111A of the HW monitor 111. The fan rotation speed controller 108A sets a new upper limit threshold and a new lower limit threshold in such a manner that the rotating speed of cooling fan [1]112a having exceeded the upper limit threshold (default value) is a center value between the new upper and lower limit thresholds. The new lower limit threshold is a value close to the original upper limit threshold (default value). The reason for resetting the status register 111b in this manner is to take measures against the subsequent detection of an abnormality of the cooling fans 112a and 112b. For example, if the rotating speed of cooling fan [2]112b becomes lower than the lower limit threshold, the fan rotation speed controller 108A recognizes the state based on an SMI generated by the Hw monitor 111 and determines that cooling fan [2]112b fails to operate normally.

On the other hand, if the rotating speed of cooling fan [1]112a becomes lower than the lower limit threshold, this may indicate that air intake port [1]11a is moved away from the wall surface and the original amount of air that should be taken in is recovered. Therefore, the fan rotation speed controller 108A sets the original rotating speed of cooling fan [2]112b. In response to this, the HW monitor 111 detects that the rotating speed of cooling fan [2]112b becomes lower than the lower limit threshold. The fan rotation speed controller 108A is notified of this state based on the operation of setting the rotating speed of cooling fan [2]112b back to the original value and resets the status register 111B of the HW monitor 111. In addition, the fan rotation speed controller 108A performs a resetting operation so that the threshold setting information 11A of the HW monitor 111 is restored to its original state.

If cooling fan [1]112a fails to operate normally, then the HW monitor 111 senses again that the rotating speed of cooling fan [1]112a becomes lower than the lower limit threshold after the resetting of the threshold setting information 111A. Therefore, the fan rotation speed controller 108A determines that cooling fan [2]112b fails to operate normally, by receiving a notice of the state.

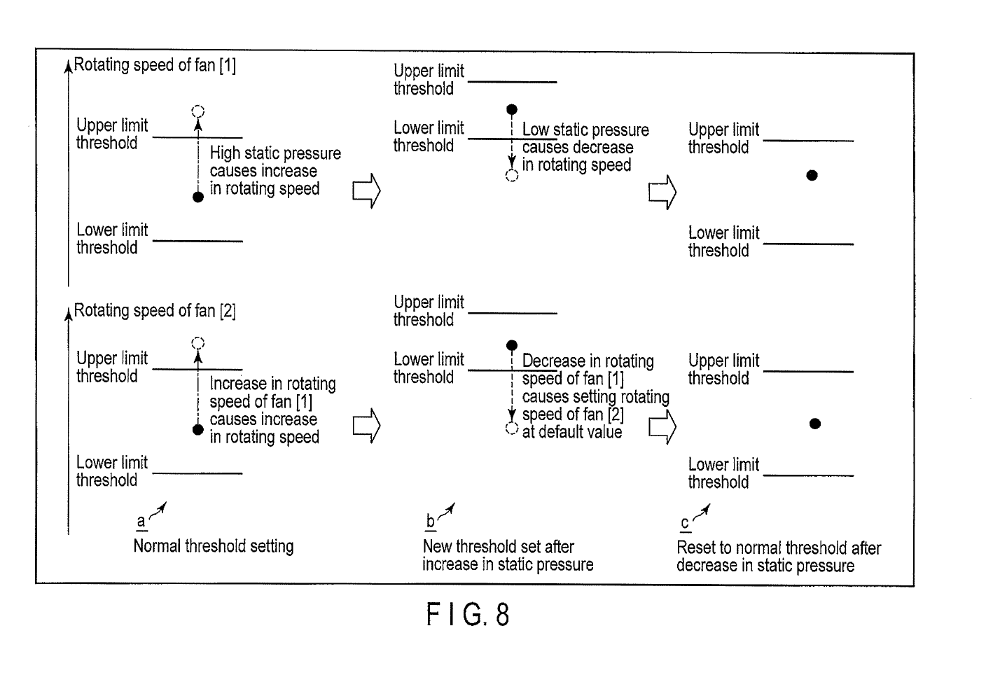

FIG. 8 is an exemplary conceptual diagram illustrating procedures for controlling the cooling fans 112a and 112b of the information processing apparatus of the second embodiment.

Let us assume that air intake port [1]11a is close to a wall surface, and the static pressure increases, causing the rotating speed of cooling fan [1]112a to exceed the upper limit threshold. Upon detection of this state, the fan rotation speed controller 108A of the BIOS 108 increases the rotating speed of cooling fan [2]112b (“a” of FIG. 8). At the time, the fan rotation speed controller 108A also resets the upper limit threshold and the lower limit threshold (“b” of FIG. 8).

If the air intake port [1]11a is moved away from the wall surface and the rotating speed of cooling fan [1]112a becomes lower than the lower limit threshold, then the fan rotation speed controller 108A sets the rotating speed of cooling fan [2]112b at the original value (“b” of FIG. 8). At the time, the fan rotation speed controller 108A also performs a resetting operation so that the upper limit threshold and the lower limit threshold are set at their original values (“c” of FIG. 8).

In the above, a description was given of the case where the rotating speed of cooling fan [1]112a exceeds the upper limit threshold, and in response to this, the rotating speed of cooling fan [2]112b is increased and the upper limit threshold and the lower limit threshold are reset. Similar control procedures are applicable to the case where the rotating speed of cooling fan [2]112b exceeds the upper limit threshold. Furthermore, similar procedures are applicable to the case where the rotating speed of one of three or more cooling fans exceeds the upper limit threshold, and the rotating speeds of the other cooling fans have to be increased.

As described above, the information processing apparatus 1 enables proper control of the rotating speed of a cooling fan regardless of whether or not the apparatus is placed with its air intake port close to a wall surface.

The control procedures of the embodiments can be realized by software (programs). Therefore, the software can be installed in an ordinary type of computer through the use of a computer-readable storage medium storing the software, and can be executed by the computer. Advantages similar to those of the above-described embodiments can be readily obtained.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processing apparatus comprising:
a housing comprising a rectangular front face and configured to be placed in either a first direction in which a first side in a longitudinal direction of the front face is vertical or a second direction in which the first side is horizontal;
a sensor configured to sense a placement direction of the housing;
a cooling fan; and
a cooling fan controller configured to control a rotating speed of the cooling fan based on a detection result of the sensor, wherein:
the housing is configured to be placed inside a rack in a third direction which is opposed to a case where the first side is horizontal, and a second side orthogonal to the first side is in the second direction; and
the cooling fan controller is further configured to set a rotating speed of the cooling fan at different values between a case where the detection result of the sensor indicates that the housing is placed in either the first direction or the second direction and a case where the detection result of the sensor indicates that the housing is placed in the third direction, such that the rotating speed of the cooling fan is controlled at different values between a case where the housing is placed outside the rack and a case where the housing is placed inside the rack.

2. The apparatus of claim 1, wherein the sensor comprises a triaxial acceleration sensor.

3. The apparatus of claim 1, wherein the cooling fan controller is further configured to set the rotating speed of the cooling fan at a larger value when the detection result of the sensor indicates that the housing is placed in the third direction than when the detection result of the sensor indicates that the housing is placed in either the first direction or the second direction.

4. The apparatus of claim 1, wherein the housing is further configured to be placed in the second direction by a foot stand perpendicular to the front face and provided on either a rectangular side face or a bottom face comprising the first side.

5. The apparatus of claim 1, wherein the housing is prevented from being placed inside the rack in the second direction by a rack mount kit attached to the housing to permit the housing to be placed in the rack, and is configured to be placed inside the rack in the third direction only.

6. The apparatus of claim 1, wherein the housing is prevented from being placed inside the rack in the second direction by either an air discharge port or an air intake port in a rectangular side face or a bottom face comprising the second side, and is configured to be placed inside the rack in the third direction only.

7. The apparatus of claim 1, wherein the front face of the housing comprises a logotype orientated in a proper direction when the housing is placed in the first direction.

8. An information processing apparatus comprising:
a plurality of cooling fans; and
a cooling fan controller configured to control rotating speeds of the cooling fans,
wherein the cooling fan controller is configured to increase rotating speeds of remaining cooling fans when a rotating speed of at least one of the cooling fans exceeds an upper limit threshold.

9. The apparatus of claim 8, wherein the cooling fan controller is further configured to increase the upper limit threshold or a lower limit threshold when the rotating speeds of the remaining cooling fans are increased.

10. The apparatus of claim 9, wherein the cooling fan controller is further configured to set the rotating speeds of the remaining cooling fans at default values when the rotating speed of the at least one of the cooling fan becomes lower than the lower limit threshold which is reset.

11. The apparatus of claim 10, wherein the cooling fan controller is further configured to reset the upper limit threshold and the lower limit threshold to default values when the rotating speeds of the remaining cooling fans are set at the default values.

12. The apparatus of claim 9, wherein the cooling fan controller is further configured to determine that the remaining cooling fans fail to operate normally when the rotating speeds of the remaining cooling fans become lower than the lower limit thresholds.

13. The apparatus of claim 9, wherein the lower limit threshold after resetting is close to the upper limit threshold before resetting.

14. A method of controlling a cooling fan for an information processing apparatus comprising a housing comprising a rectangular front face and configured to be placed in either a first direction in which a first side in a longitudinal direction of the front face is vertical or a second direction in which the first side is horizontal, the method comprising:
configuring the housing to be placed inside a rack in a third direction which is opposed to a case where the first side is horizontal and a second side orthogonal to the first side is in the second direction;
detecting a placement direction of the housing from among the first direction, the second direction and the third direction; and
setting a rotating speed of the cooling fan at different values between a case where the housing is detected as being placed in either the first direction or the second direction and a case where the housing is detected as being placed in the third direction, such that the rotating speed of the cooling fan is controlled at different values between a case where the housing is placed outside the rack and a case where the housing is placed inside the rack.
